(19) United States
(12) Patent Application Publication
(10) Pub. No.: US 2021/0071070 A1
(43) Pub. Date: Mar. 11, 2021

(54) ELECTROLUMINESCENT DEVICE AND METHOD OF MANUFACTURING THE SAME, DISPLAY PANEL AND DISPLAY APPARATUS

(71) Applicants: BOE TECHNOLOGY GROUP CO., LTD., Chacyang District (CN); BEIJING JIAOTONG UNIVERSITY, Bejing (CN)

(72) Inventors: Bo QIAO, Beijing (CN); Zheng XU, Beijing (CN); Xiao WU, Beijing (CN)

(73) Assignees: BOE TECHNOLOGY GROUP CO., LTD., Beijing (CN); BEIJING JIAOTONG UNIVERSITY, Beijing (CN); BEIJING JIAOTONG UNIVERSITY, Beijing (CN)

(21) Appl. No.: 16/466,250

(22) PCT Filed: Sep. 27, 2018
(86) PCT No.: PCT/CN2018/107920

§ 371 Date: Jun. 3, 2019

(30) Foreign Application Priority Data
Dec. 15, 2017 (CN) 201711349428.7

(51) Int. Cl. C09K 11/00; H01L 51/50; H01L 51/56

(52) U.S. Cl. CPC C09K 11/00; H01L 51/502; H01L 51/5016; H01L 51/5056; H01L 51/5072; H01L 51/56

(57) ABSTRACT

Some embodiments of the present disclosure provide an electroluminescent device and a method of manufacturing the same, a display panel and a display apparatus. The electroluminescent device includes a first electrode and a second electrode disposed oppositely. A composite functional layer is disposed between the first electrode and the second electrode, and the composite functional layer includes a thermally activated delayed fluorescence material and a luminescent material. The thermally activated delayed fluorescence material is configured to capture carriers that are not recombined in the luminescent material so as to generate excitons which are then transferred to the luminescent material.

### CROSS-REFERENCE TO RELATED APPLICATION

This application is a national phase entry under 35 USC 371 of International Patent Application No. PCT/CN2018/107920 filed on Sep. 27, 2018, which claims priority to Chinese Patent Application No. 201711349428.7, filed with the Chinese Patent Office on Dec. 15, 2017, titled “ELECTROLUMINESCENT DEVICE AND METHOD OF MANUFACTURING THE SAME, DISPLAY PANEL AND DISPLAY APPARATUS”, which are incorporated herein by reference in their entirety.

### TECHNICAL FIELD

The present disclosure relates to the field of display technologies, and in particular, to an electroluminescent device and a method of manufacturing the same, a display panel and a display apparatus.

### BACKGROUND

In an electroluminescent device, electrons and holes respectively injected from the electrodes on both sides under the driven of an external voltage are recombined in a light-emitting layer to generate excitons, and the excitions transport energy to luminescent molecules to excite the luminescent molecules to emit light.

### SUMMARY

In a first aspect, an electroluminescent device is provided. The electroluminescent device includes: a first electrode and a second electrode disposed oppositely; and composite functional layer(s) disposed between the first electrode and the second electrode. Each composite functional layer includes thermally activated delayed fluorescence material and luminescent material. The thermally activated delayed fluorescence material is configured to capture carriers that are not recombined in the luminescent material so as to generate excitons which are then transferred to the luminescent material.

In some embodiments of the present disclosure, the composite functional layer includes a carrier collection layer and a light-emitting layer. The carrier collection layer includes the thermally excited delayed fluorescent material. The light-emitting layer includes the luminescent material.

In some embodiments of the present disclosure, the carrier collection layer is disposed on a surface of the light-emitting layer close to the second electrode.

In some embodiments of the present disclosure, the first electrode is a cathode, and the second electrode is an anode.

In some embodiments of the present disclosure, the light-emitting layer is a quantum dot light-emitting layer.

In some embodiments of the present disclosure, a luminescence spectrum of the thermally activated delayed fluorescence material and an absorption spectrum of quantum dots in the quantum dot light-emitting layer have an overlap wavelength range.

In some embodiments of the present disclosure, the quantum dots are green light quantum dots, and the thermally activated delayed fluorescence material is blue thermal activated delayed fluorescence material.

In some embodiments of the present disclosure, the blue light thermally activated delayed fluorescence material includes Bis [4-(9,9-dimethyl-9,10-dihydroacridine) phenyl] solfone.

In some embodiments of the present disclosure, the cathode is made of transparent conductive material and the anode is made of metal material.

In some embodiments of the present disclosure, the electroluminescent device further includes an electron-transporting layer disposed between the cathode and the light-emitting layer, and a hole-transporting layer and a hole injection layer that are disposed between the carrier collection layer and the anode, and disposed sequentially away from the carrier collection layer.

In a second aspect, a method of manufacturing an electroluminescent device is provided. A first electrode of the electroluminescent device is a cathode, and a second electrode of the electroluminescent device is an anode. The method includes steps of forming the cathode and the anode disposed oppositely. A composite functional layer of the electroluminescent device includes a carrier collection layer and a light-emitting layer. The method further includes: forming the light-emitting layer between the cathode and the anode, the light-emitting layer including luminescent material; and forming the carrier collection layer on a surface of the light-emitting layer close to the anode, the carrier collection layer including thermally activated delayed fluorescence material. And/or, the method further includes: doping the luminescent material into the thermally activated delayed fluorescence material to form the composite functional layer. The thermally activated delayed fluorescence material is configured to capture carriers that are not recombined in the luminescent material so as to generate excitons which are transferable to the luminescent material.

In some embodiments of the present disclosure, the method further includes: forming an electron-transporting layer on a surface of the cathode close to the anode by a solution method; and forming a hole-transporting layer and a hole injection layer sequentially on a surface of the composite functional layer close to the anode by a vapor deposition method.

In a third aspect, a display panel is provided, comprising the above electroluminescent device.

In some embodiments of the present disclosure, the display panel includes a plurality of display units. Each display unit includes a single electroluminescent device.

In a fourth aspect, a display apparatus is provided, including the above display panel.

### BRIEF DESCRIPTION OF THE DRAWINGS

In order to describe technical solutions in embodiments of the present disclosure more clearly, the accompanying drawings to be used in the description of embodiments will be introduced briefly. Obviously, the accompanying drawings to be described below are merely some embodiments of the present disclosure, and a person of ordinary skill in the art can obtain other drawings according to these drawings without paying any creative effort.

FIG. 1 is a schematic structural diagram of an electroluminescent device, in accordance with some embodiments of the present disclosure;

FIG. 2 is a schematic structural diagram of another electroluminescent device, in accordance with some embodiments of the present disclosure;

FIG. 3 is a schematic structural diagram of yet another electroluminescent device, in accordance with some embodiments of the present disclosure;

FIG. 4 is a schematic structural diagram of yet another electroluminescent device, in accordance with some embodiments of the present disclosure;

FIG. 5 shows a PL spectrum of blue light thermally activated delayed fluorescence (TADF) material and an absorption spectrum of green light quantum dots (QDs) in an electroluminescent device, in accordance with some embodiments of the present disclosure;

FIG. 6 shows a PL spectrum of green light QDs in an electroluminescent device, in accordance with some embodiments of the present disclosure;

FIG. 7 is a diagram showing energy levels of layers in an electroluminescent device, in accordance with some embodiments of the present disclosure;

FIG. 8 is a flow diagram of a method of manufacturing an electroluminescent device, in accordance with some embodiments of the present disclosure; and

FIG. 9 is a schematic structural diagram of a display panel, in accordance with some embodiments of the present disclosure.

### DETAILED DESCRIPTION

The technical solutions in embodiments of the present disclosure will be described clearly and completely with reference to the accompanying drawings in embodiments of the present disclosure. Obviously, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

It will be noted that, unless otherwise defined, all terms (including technical and scientific terms) used in embodiments of the present disclosure have the same meaning as commonly understood by one of ordinary skill in the art to which this disclosure belongs. It will also be understood that terms such as those defined in the ordinary dictionary should be interpreted as having meanings consistent with their meaning in the context of the related art, and not interpreted in an idealized or extremely formalized meaning unless explicitly defined herein.

For example, the terms “first”, “second” and similar terms used in the present description and the claims are not intended to mean any order, quantity or importance, and are merely used to distinguish different components. The words “include” or “comprise”, etc. are intended to mean that an element or object that precedes the word includes an element or object listed after the word and equivalents thereof, and does not exclude other element or object. Orientations or positional relationships indicated by terms “upper/above”, “lower/below”, etc. are based on orientations or positional relationships shown in the accompanying drawings, merely for the convenience of explaining simplified descriptions of the technical solutions of the present disclosure, but not to indicate or imply that the referred devices or elements must have a particular orientation, or must be constructed or operated in a particular orientation. Therefore they should not be construed as limitations to the present disclosure.

In an electroluminescent device, electron mobility is generally greater than hole mobility. In this case, when an external voltage is applied across the electrodes of the electroluminescent device to drive the electroluminescent device to emit light, there is an imbalance between the electron current and the hole current. In this case, some of the electrons leak through the light-emitting layer and cannot be recombined with the holes to generate excitons. The electron current (i.e., leakage current) produced by the above electrons that are not recombined with holes cannot be used for light emission, thereby reducing the electro-optical conversion efficiency of the electroluminescent device.

In order to solve the above problem, some embodiments of the present disclosure provide an electroluminescent device. The electroluminescent device, as shown in FIG. 1, includes a first electrode 10 and a second electrode 20 disposed opposite to each other, and a composite functional layer 301 disposed between the first electrode 10 and the second electrode 20.

In some embodiments of the present disclosure, the first electrode 10 is configured to generate electrons in a powered state (e.g., when a negative “−” voltage is applied), and the second electrode 20 is configured to generate holes in a powered state (e.g., when a positive “+” voltage is applied). Therefore, the first electrode 10 is a cathode and the second electrode 20 is an anode. Alternatively, in some embodiments of the present disclosure, the first electrode 10 is configured to generate holes in a powered state, and the second electrode 20 is configured to generate electrons in a powered state. In this case, the first electrode 10 is an anode and the second electrode 20 is a cathode. Hereinafter, for convenience of explanation, the description will be made by taking an example in which the first electrode 10 can be a cathode and the second electrode 20 is an anode.

In some embodiments of the present disclosure, the first electrode 10 can be made of transparent conductive material (such as indium tin oxide (ITO)), and the second electrode 20 can be made of metal material (such as aluminum (Al)).

In addition, the composite functional layer 301 includes thermally activated delayed fluorescence (abbreviated as TADF) material and luminescent material.

The TADF material is configured to capture carriers that are not recombined in the luminescent material, such as electrons having a larger mobility. The carriers are recombined with holes generated by the second electrode 20 to form excitons, and the excitons are transferred to the above luminescent material. The above TADF material is a third generation organic luminescent material developed after organic fluorescent materials and organic phosphorescent materials. The TADF material generally has a small singlet-triplet energy difference (DEST). Triplet excitons may be changed to singlet excitons through a reverse intersystem crossing (RISC) process at room temperature by using internal energy of molecules themselves, so that the singlet excitons and triplet excitons generated under electrical excitation may be fully utilized. Therefore, an internal quantum efficiency of the TADF material may reach 100%, and electrons and holes may easily form excitons in the TADF material. In addition, the TADF material is controllable in structure, stable in property, and low in cost, and no precious metals are required.

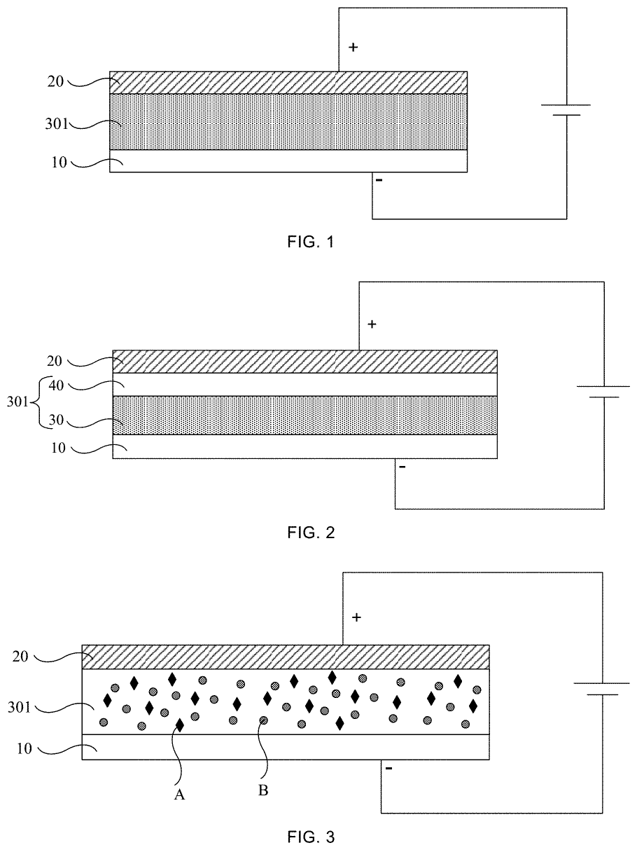

In some embodiments of the present disclosure, as shown in FIG. 2, the composite functional layer 301 includes a carrier collection layer 40 and a light-emitting layer 30.

The carrier collection layer 40 includes the above TADF material. The light-emitting layer 30 includes the luminescent material.

In the electroluminescent device, since the electron mobility is greater than the hole mobility, the position of the luminescent center formed by the recombination of electrons and holes in the light-emitting layer 30 is at a side of the light-emitting layer 30 close to the second electrode 20 used for supplying holes. In addition, electrons leaking through the light-emitting layer 30 are also easily concentrated on the side of the light-emitting layer 30 close to the second electrode 20.

Therefore, in order to improve a luminous efficiency of the electroluminescent device, as shown in FIG. 2, the carrier collection layer 40 is disposed on a surface of the light-emitting layer 30 close to the second electrode 20. In this way, the carrier collection layer 40, mainly made of the TADF material having a high utilization rate of the excitons, is provided on the surface of the light-emitting layer 30 close to the second electrode 20 in the form of modifying the light-emitting layer 30. The carrier collection layer 40 may capture and accumulate the carriers that have leaked through (or referred to as passing through) the light-emitting layer 30, such as electrons supplied by the first electrode 10. Then, the electrons captured and accumulated in the carrier collection layer 40 may be recombined with holes injected from the adjacent second electrode 20 to form excitons, and energy of the excitons may be transferred back to the luminescent material in the light-emitting layer 30, thereby exciting the luminescent material to emit light. As described above, electrons that are not recombined with holes in the luminescent material of the light-emitting layer 30 may be recombined again with the holes supplied by the second electrode 20 in the carrier collection layer 40 to form excitons, and the excitons are transferred to the light-emitting layer 30, so that electrons that are not recombined with the holes in the luminescent material may be used for light emission, which is advantageous for increasing an utilization ratio of carriers and improving the luminous efficiency of the electroluminescent device.

In some other embodiments of the present disclosure, as shown in FIG. 3, materials of the composite functional layer 301 include a mixture of the TADF material A and the luminescent material B. In this case, the TADF material A can be added to the luminescent material B in a doped form, so that the composite functional layer 301 intercepts electrons that have leaked through (or referred to as passing through) the luminescent material B, and the electrons are recombined with holes injected from the second electrode 20 to form excitons. Then, the energy of the excitons are transferred from the TADF material A back to the luminescent material B, thereby exciting the luminescent material B to emit light, which is advantageous for increasing the utilization ratio of carriers and improving the luminous efficiency of the electroluminescent device.

The above electroluminescent device provided by some embodiments of the present disclosure includes at least one composite functional layer 301. In a case where the electroluminescent device may have a single composite functional layer 301, the composite functional layer 301 may include the light-emitting layer 30 and the carrier collection layer 40 stacked on top of one another, and the carrier collection layer 40 is disposed on the surface of the light-emitting layer 30 close to the second electrode 20. Optionally, in a case where the electroluminescent device may include a single composite functional layer 301, the materials of the composite functional layer 301 include a mixture of the TADF material A and the luminescent material B. Optionally, in a case where the electroluminescent device may include two composite functional layers 301, one composite functional layer 301 includes the light-emitting layer 30 and the carrier collection layer 40 stacked on top of one another, another composite functional layer 301 is made of a mixture of the TADF material A and the luminescent material B. Some embodiments of the present disclosure are not limited thereto, and the structure can be flexibly adjusted according to factors such as specific design requirements of devices and selection of materials.

As can be seen from the above, in the electroluminescent device provided by some embodiments of the present disclosure, the composite functional layer 301 captures electrons that are not recombined with holes in the luminescent material, so that the electrons are recombined with holes in the composite functional layer 301 to form excitons. The energy of the excitons is transferred to the luminescent material, which may increase the utilization ratio of carriers in the electroluminescent device, thereby improving the luminous efficiency of the electroluminescent device.

In addition, since quantum dot material has advantages such as adjustable color of emitted light, high luminous efficiency and narrow linewidth (less than 30 nm) of the emitted light, the electroluminescent device formed by the quantum dot material has a wide color gamut. The quantum dot material can also be synthesized by a solution method, and thus can be further applied to the field of flexibile display apparatus. Due to the above advantages, the quantum dot material is considered as the core of a third-generation display technology by the industry and has great advantages in the field of display illumination.

In some embodiments of the present disclosure, the electroluminescent device can be a quantum dot electroluminescent device, and the luminescent material in the quantum dot electroluminescent device is quantum dot luminescent material, and the luminescent substances in the luminescent material are quantum dots.

For example, in a case where the composite functional layer 301 includes the above light-emitting layer 30 and the carrier collection layer 40 stacked on top of one another, the light-emitting layer 30 is a quantum dot light-emitting layer.

For another example, the material of the composite functional layer 301 can be a mixture of the quantum dot luminescent material and the TADF material.

In this way, by providing the carrier collection layer 40 on the surface of the quantum dot light-emitting layer close to the second electrode 20, or doping the TADF material into the quantum dot luminescent material to form the above composite functional layer 301, the TADF material may capture electrons that leak through the luminescent material and are not recombined with holes, and the electrons are recombined with holes injected from the second electrode 20 in the TADF material to form excitons. Then, the energy of the excitons is transferred from the TADF material back to the quantum dots, thereby exciting the quantum dots to emit light, which is beneficial to increase the utilization ratio of carriers, improve the luminous efficiency of the electroluminescent device, and enable the quantum dot electroluminescent device to be better applied to the field of display illumination.

In this case, in order to enable the TADF material to transfer the generated excitons back to the quantum dots, on the one hand, a luminescence spectrum \textcircled{1} of the selected TADF material (shown in FIG. 5) has an overlap wavelength range with an absorption spectrum \textcircled{2} of the quantum dots. In this case, spectra of the two materials have intensity or absorbance (as shown on a vertical axis of FIG. 5) in a same wavelength range (the range is related to selected TADF material and quantum dot luminescent material, and not limited in the embodiments of the present disclosure). For example, the luminescence spectrum \textcircled{1} has a certain luminous intensity (i.e., EL intensity) in a range of 400 nm-600 nm on a horizental axis of FIG. 5, and the absorption spectrum \textcircled{2} has a certain absorbance in the range of 400 nm-600 nm on the horizontal axis of FIG. 5, so that the energy of the excitons generated in the TADF material may be utilized by the quantum dots.

On the other hand, a valence band energy level of the TADF material is close to a valence band energy level of the quantum dot (absolute value of a difference between the energy levels is usually less than 0.3 eV). In this case, in a case where the carrier collection layer 40 made of the TADF material is formed on the surface of the quantum dot light-emitting layer, the distance between the molecules of the TADF material and the quantum dot at an interface between the carrier collection layer 40 and the light-emitting layer 30 is less than the radius of Forster energy transfer. In a case where the TADF material is doped in the quantum dot luminescent material to form the composite functional layer 301, the distance between the molecules of the TADF material and the quantum dots is also less than the radius of the Forster energy transfer, thereby achieving a high probability of Forster energy transfer from the thermally activated delayed fluorescent material to the quantum dots.

In some embodiments, the quantum dots can be green light quantum dots. Since a wavelength range of green light emitted by the green light quantum dots is greater than a wavelength range of blue light, the corresponding TADF material can be blue light thermally activated delayed fluorescence material (blue light TADF material). In this way, the excitons generated in the TADF material have energy greater than energy required for the green light quantum dots to emit green light, so that the energy transferred to the green light quantum dots may be utilized to excite them to emit green light.

In some embodiments, the blue TADF material includes DMAC-DPS-like material with relatively stable performance, the Chines name of which is [symbol] [4-(9,9- [symbol] -9,10- [symbol] ) [symbol] ] [symbol] , and the English name of which is Bis [4-(9,9-dimethyl-9,10-dihydroacridine) phenyl] solfone.

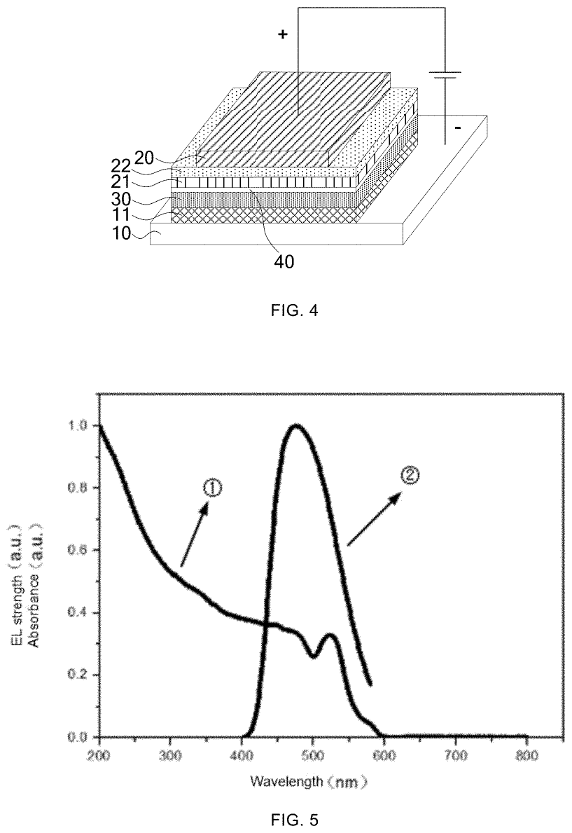

In addition, referring to FIG. 4, the above electroluminescent device further includes: an electron-transporting layer 11 disposed between the first electrode 10 and the light-emitting layer 30, and a hole-transporting layer 21 and a hole injection layer 22 (for increasing the injection efficiency of hole carriers) that are disposed between the carrier collection layer 40 and the second electrode 20, and disposed sequentially away from the carrier collection layer 40.

In addition, in some embodiments of the present disclosure, the electroluminescent device can be a normal device in which the first electrode 10 is made of metal material (such as Al) and the second electrode 20 is made of transparent conductive material (such as ITO). In this case, the first electrode 10 is a cathode and the second electrode 20 is an anode. In some other embodiments of the present disclosure, the above electroluminescent device can be an inverted device. For example, the first electrode 10 is made of transparent conductive material (such as ITO), and the second electrode 20 is made of metal material (such as Al). In this case, the first electrode 10 is still a cathode and the second electrode 20 is still an anode.

The materials of the second electrode 20 of the inverted device and the first electrode 10 of the normal device are the same, and the materials of the first electrode 10 of the inverted device and the second electrode 20 of the normal device are the same, so that a problem that an anode of ITO in the normal device is easily corroded by the hole-transporting layer 21 and an cathode of Al with the low-work function in the normal device is easily oxidized may be solved. The structure in which the materials of the second electrode 20 and the first electrode 10 are exchanged may have a positive effect.

Referring to the foregoing FIG. 4, some embodiments of the present disclosure provide a quantum dot electroluminescent device including the following structure.

A substrate having an ITO conductive electrode is provided as a base, and the ITO conductive electrode is used as the first electrode 10.

An electron-transporting layer 11 is disposed on the surface of the first electrode 10.

The material of the above electron-transporting layer 11 includes ZnO NP solution. The preparation method of the ZnO NP solution is to disperse ZnO NPs in ethanol solvent. The ZnO NPs refer to ZnO Nanoparticles.

In addition, the quantum dot electroluminescent device further includes a green light quantum dot light-emitting layer 30 disposed on the surface of the electron-transporting layer 11.

The carrier collection layer 40 is disposed on a surface of the green light quantum dot light-emitting layer 30. The carrier collection layer 40 is made of the TADF material, such as DMAC-DPS material, and has a thickness of 5 nm. The carrier collection layer 40 has a small thickness and can be used to modify the green light quantum dot light-emitting layer 30.

In addition, the quantum dot electroluminescent device further includes a hole-transporting layer 21 disposed on a surface of the carrier collection layer 40. The hole-transporting layer 21 is made of CBP (4,4′-bis(N-carbazole)-1,1′-biphenyl) material and has a thickness of 40 nm.

A hole injection layer 22 is disposed on a surface of the hole-transporting layer 21. The hole injection layer 22 is made of HAT-CN (2,3,6,7,10,11-hexacyano-1,4,5,8,9,12-hexaazatriphenylene) material and has a thickness of 15 nm.

A second electrode 20 is disposed on a surface of the hole injection layer 22, and the second electrode 20 is made of Al and has a thickness of 100 nm.

In addition, a photoluminescence spectroscopy (PL) spectrum \textcircled{2} of the blue light TADF material (for forming the carrier collection layer 40) and an absorption spectrum \textcircled{1} of the green light quantum dots (QDs) are shown in FIG. 5, and it can be seen that the spectra of the two materials have an overlap wavelength range.

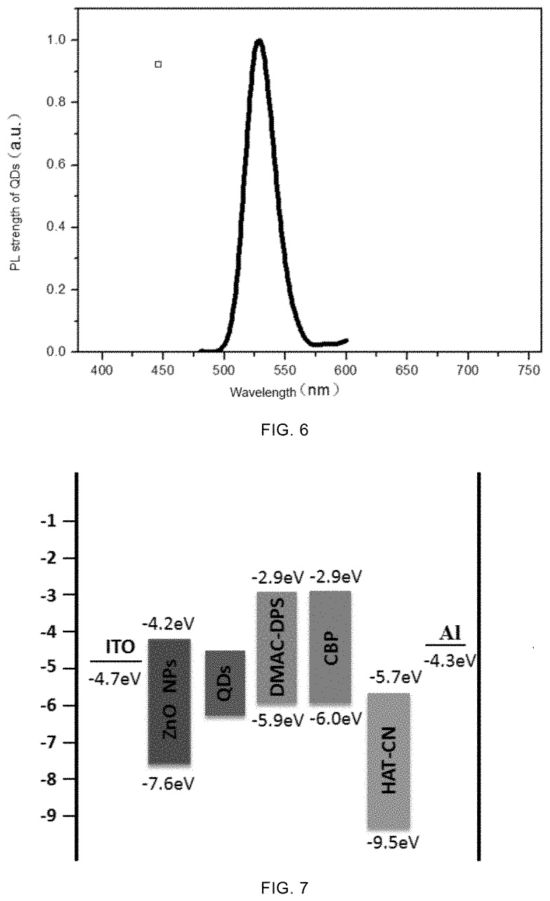

As shown in FIG. 6, the luminescence peak of the PL spectrum of the green light QDs is approximately 530 nm.

In addition, a diagram showing energy levels of layers in the above quantum dot electroluminescent device is as shown in FIG. 7, and it can be seen that the energy levels of layers match each other, and the valence band (−5.9 eV˜−2.9 eV) of the carrier collection layer 40 is very close to the valence band (−6.0 eV˜−2.9 eV) of the green light quantum dot light-emitting layer 30, and the Forster energy transfer from the TADF material to the quantum dots may be realized with a high probability.

The electroluminescent spectrum of the above green light quantum dot electroluminescent device is measured by a spectroradiometer, the device model of which is Spectroradiometer CR-250. The absorption spectrum of the green light QDs is measured by a spectrometer, the device model of which is Shimadzu UV-3101 PC spectrometer. The PL steady-state spectra of the blue light TADF material and the green light QD light-emitting layer are measured by a fluorescence spectrometer, the device model of which is Horiba Fluorolog-3.

It will be noted that the above description is made by taking an example in which the carrier collection layer 40 includes the blue light TADF material and the material of the light-emitting layer is green light quantum dot luminescent material. In a case where the material of the light-emitting layer is other quantum dot luminescent materials, the material of the carrier collection layer 40 can be changed as long as the carrier collection layer 40 may transfer the generated excitons to the quantum dot light-emitting layer, which is not limited by the present disclosure.

Some embodiments of the present disclosure provide a method of manufacturing an electroluminescent device. In a case where a first electrode 10 of the electroluminescent device is a cathode and a second electrode 20 of the electroluminescent device is an anode, the above manufacturing method includes steps of forming a cathode and an anode disposed opposite to each other.

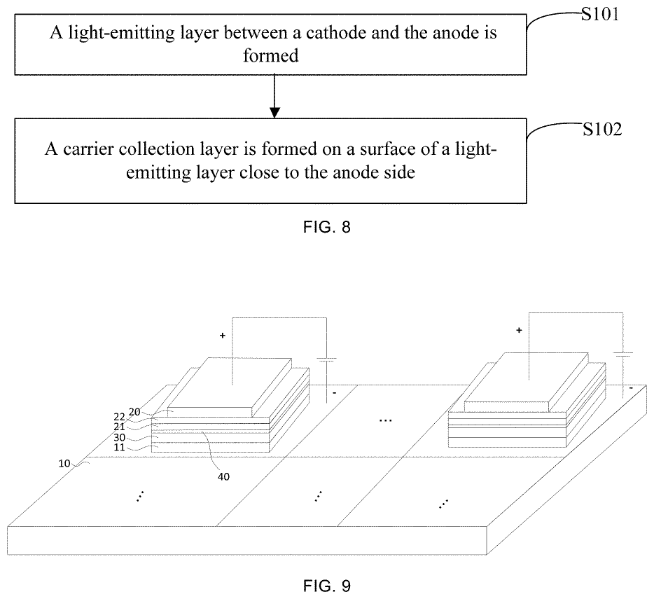

In some embodiments, in a case where a composite functional layer 301 of the electroluminescent device includes a carrier collection layer 40 and a light-emitting layer 30 as shown in FIG. 2, the above manufacturing method further includes S101 and S102 in addition to steps of forming the cathode and the anode disposed opposite to each other, as shown in FIG. 8.

In S101, the light-emitting layer 30 is formed between the cathode and the anode.

The light-emitting layer includes luminescent material. The light-emitting layer 30 (especially the quantum dot light-emitting layer) is usually a polymer, and thus is prepared by a solution method including spin coating, ink jet printing, or the like.

In S102, the carrier collection layer 40 is formed on a surface of the light-emitting layer 30 close to the anode.

The carrier collection layer 40 is mainly made of TADF material.

In some embodiments, in addition to steps of forming the cathode and the anode disposed opposite to each other, in a case where the structure of the composite functional layer 301 of the electroluminescent device is as shown in FIG. 3, the above method further includes:

forming the composite functional layer by doping the TADF material into the luminescent material.

The TADF material is configured to capture carriers that are not recombined in the luminescent material so as to generate excitons which are tranferreable to the luminescent material.

Further, the above manufacturing method further includes: forming an electron-transporting layer 11 as shown in FIG. 4 on a surface of the cathode by a solution method. The electron-transporting layer 11 usually includes semiconductor nanoparticles dispersed in a solvent; and

forming the hole-transporting layer 21 and the hole injection layer 22 sequentially on the surface of the light-emitting layer 30 by a vapor deposition method.

It will be noted that, the carrier collection layer 40, the hole-transporting layer 21, the hole injection layer 22, and the anode are either small molecule layers or metal material layers prepared by the vapor deposition method to obtain film layers having a dense structure and few defects.

Some embodiments of the present disclosure provide a process for preparing a quantum dot electroluminescent device, and the process includes but not limited to the following steps.

In step 1, an ITO cathode is provided, and the ITO cathode is cleaned for a subsequent spin coating process.

The ITO cathode is a substrate having an ITO conductive electrode.

In addition, the cleaning process can, for example, include the following sub-steps: after the substrate having the ITO conductive electrode is wiped clean with cotton wool, a surface of the substrate is ultrasonically treated with deionized water and alcohol in turn. After drying with nitrogen, the substrate was transferred into a glove box for the subsequent spin coating process.

In step 2, an electron-transporting layer is formed on a surface of the ITO cathode.

For example, step 2 may include the following sub-steps: a ZnO electron-transporting layer is spin coated using a homogenizer at a rotational speed of 3000 rpm for 45 s. After the spin coating, the substrate spin-coated with ZnO is placed on a heating platform at 70° C. for annealing for 25 minutes to eliminate residual stress in the formed ZnO film and reduce structural defects in the film.

In step 3, a green light quantum dot light-emitting layer is formed on a surface of the electron-transporting layer 11.

For example, step 3 may include the following sub-steps. The green light quantum dot light-emitting layer is formed on the surface of the electron-transporting layer 11 by spin coating. The concentration of green light quantum dots in the green light quantum dot light-emitting layer is 12.5 mg/mL, the solvent is hexane, and the spin coating is performed at 70° C. for 25 minutes.

In step 4, a carrier collection layer 40, a hole-transporting layer 21, a hole injection layer 22 and an anode are sequentially formed on a surface of the green light quantum dot light-emitting layer.

For example, step 4 may include the following sub-steps. The substrate formed in the foregoing steps is placed into a vacuum thermal evaporation chamber, and the carrier collection layer (DMAC-DPS), the hole-transporting layer (CBP), the hole injection layer (HAT-CN) and the Al are sequentially vaporized. The layers have thicknesses of 5 nm, 40 nm, 15 nm, and 100 nm respectively. The vacuum degree is less than 5×10⁻⁴ Pa.

As shown in FIG. 9, some embodiments of the present disclosure provide a display panel including the above electroluminescent device.

The display panel may further be a self-luminous display device, that is, the display panel includes a plurality of display units, each of which includes a single electroluminescent device.

Each display unit further includes a thin film transistor (TFT) for driving the electroluminescent device for display, thereby realizing an active matrix (AM) display mode. The display unit may be manufactured by combining the above electroluminescent device and the TFT with certain package into a module.

Of course, the above electroluminescent device can also be used as a light source to provide backlight for a passive light emission display panel such as a liquid crystal display panel.

Some embodiments of the present disclosure provide a display apparatus, and the display apparatus includes the display panel. The display apparatus maybe a product or a component having any display function, such as a television, a digital photo frame, a mobile phone, a tablet computer, a navigator, and a wearable device (such as a smart wristband).

The foregoing descriptions are merely some specific implementation manners of the present disclosure, but the protection scope of the present disclosure is not limited thereto. Any person skilled in the art could readily conceive of changes or replacements within the technical scope of the present disclosure, which shall all be included in the protection scope of the present disclosure. Therefore, the protection scope of the present disclosure shall be subject to the protection scope of the claims.

1. An electroluminescent device, comprising:
a first electrode and a second electrode disposed oppositely; and,
composite functional layer(s) disposed between the first electrode and the second electrode, wherein each composite functional layer includes thermally activated delayed fluorescence material and luminescent material, the thermally activated delayed fluorescence material is configured to capture carriers that are not recombined in the luminescent material so as to generate excitons which are transferable to the luminescent material.

2. The electroluminescent device according to claim 1, wherein
the composite functional layer includes a carrier collection layer and a light-emitting layer; and
the carrier collection layer includes the thermally activated delayed fluorescence material, and the light-emitting layer includes the luminescent material.

3. The electroluminescent device according to claim 2, wherein, the carrier collection layer is disposed on a surface of the light-emitting layer close to the second electrode.

4. The electroluminescent device according to claim 3, wherein, the first electrode is a cathode and the second electrode is an anode.

5. The electroluminescent device according to claim 4, wherein, the light-emitting layer is a quantum dot light-emitting layer.

6. The electroluminescent device according to claim 5, wherein, a luminescence spectrum of the thermally activated delayed fluorescence material and an absorption spectrum of quantum dots in the quantum dot light-emitting layer have an overlap wavelength range.

7. The electroluminescent device according to claim 6, wherein, the quantum dots are green light quantum dots and the thermally activated delayed fluorescence material is blue light thermally activated delayed fluorescence material.

8. The electroluminescent device according to claim 7, wherein, the blue light thermally activated delayed fluorescence material includes Bis [4-(9,9-dimethyl-9,10-dihydroacridine) phenyl] solfone.

9. The electroluminescent device according to claim 4, wherein, the cathode is made of transparent conductive material and the anode is made of metal material.

10. The electroluminescent device according to claim 4, wherein, the electroluminescent device further comprises:
an electron-transporting layer disposed between the cathode and the light-emitting layer; and
a hole-transporting layer and a hole injection layer that are disposed between the carrier collection layer and the anode, and disposed sequentially away from the carrier collection layer.

11. A method for manufacturing an electroluminescent device, a first electrode of the electroluminescent device being a cathode and a second electrode of the electroluminescent device being an anode, and the method comprising: steps of forming the cathode and the anode disposed oppositely, wherein
a composite functional layer of the electroluminescent device includes a carrier collection layer and a light-emitting layer, and the method further comprises:
forming the light-emitting layer between the cathode and the anode, wherein the light-emitting layer includes luminescent material; and
forming the carrier collection layer on a surface of the light-emitting layer close to the anode, wherein the carrier collection layer includes thermally activated delayed fluorescence material;
and/or, the method further comprises:
doping the luminescent material into the thermally activated delayed fluorescence material to form the composite functional layer, wherein
the thermally activated delayed fluorescence material is configured to capture carriers that are not recombined in the luminescent material so as to generate excitons which are transferable to the luminescent material.

12. The method of manufacturing the electroluminescent device according to claim 11, wherein the method further comprises:
forming an electron-transporting layer on a surface of the cathode close to the anode by a solution method; and
forming a hole-transporting layer and a hole injection layer sequentially on a surface of the composite functional layer close to the anode by a vapor deposition method.

13. A display panel, comprising the electroluminescent device according to claim 1.

14. The display panel according to claim 13, wherein, the display panel comprises a plurality of display units; and
each display unit includes a single electroluminescent device.

15. A display apparatus, comprising the display panel according to claim 13.

16. The electroluminescent device according to claim 1, wherein materials of the composite functional layer include a mixture of the thermally activated delayed fluorescence material and the luminescent material.

17. The electroluminescent device according to claim 1, wherein the electroluminescent device comprises at least two composite functional layers;
each of at least one of the at least two composite functional layers includes a carrier collection layer and a light-emitting layer, the carrier collection layer includes the thermally activated delayed fluorescence material, and the light-emitting layer includes the luminescent material; and
materials of each of remaining composite functional layer(s) include a mixture of the thermally activated delayed fluorescence material and the luminescent material.

18. The electroluminescent device according to claim 16, wherein materials of the composite functional layer include a mixture of the thermally activated delayed fluorescence material and quantum dot luminescent material.
